(19) United States
(12) Patent Application Publication
(10) Pub. No.: US 2024/0206063 A1
(43) Pub. Date: Jun. 20, 2024

(54) CIRCUIT BOARD AND METHOD OF FABRICATING CIRCUIT BOARD

(71) Applicant: SAMSUNG ELECTRO-MECHANICS CO., LTD., Suwon-si (KR)

(72) Inventors: Seong Ho Choi, Suwon-si (KR); Seongil Jeon, Suwon-si (KR)

(73) Assignee: SAMSUNG ELECTRO-MECHANICS CO., LTD., Suwon-si (KR)

(21) Appl. No.: 18/199,743

(22) Filed: May 19, 2023

(30) Foreign Application Priority Data
Dec. 19, 2022 (KR) 10-2022-0178096

(51) Int. Cl. H05K 1/11; H05K 3/46

(52) U.S. Cl. CPC H05K 1/111; H05K 3/4644; H05K 2203/049

(57) ABSTRACT

A circuit board includes: a substrate having a first surface and a second surface opposing each other; a first connection pad protruding from the first surface in a first direction perpendicular to the first surface of the substrate and having an upper surface and a side surface intersecting each other; a first conductive layer disposed on the upper surface of the first connection pad; and a second conductive layer disposed in contact with an upper surface of the first conductive layer and the side surface of the first connection pad.

### CROSS-REFERENCE TO RELATED APPLICATION

This application claims priority to and the benefit of Korean Patent Application No. 10-2022-0178096 filed in the Korean Intellectual Property Office on Dec. 19, 2022, the entire contents of which are incorporated herein by reference.

### TECHNICAL FIELD

The present disclosure relates to a circuit board and a method of fabricating a circuit board.

### BACKGROUND

As electronic devices have gradually improved in performance in accordance with the development of the electronic industry, semiconductor packages are required to have high density while being small in size/thickness. As the number of ICs mounted to increase a density of a package increases, the number of I/O connection terminals also increases, and as a result, it is necessary to secure a process capability for implementing a microcircuit with a reduced bonding pad pitch.

Wire and flip bonding are used as current IC mounting methods for a high-density package. When the number of I/O connection terminals is larger than a predetermined level, flip bonding is preferred in consideration of the cost required for mounting ICs.

However, even in a case where a wire bonding chip is mounted, a bond finger implemented by a microcircuit is required, and a nickel plating layer is formed to have a wire bonding environment. At this time, it is required to implement a bonding pad with a fine pitch by preventing the nickel plating layer from spreading to the left and right of the bonding pad.

The above information disclosed in this Background section is only for enhancement of understanding of the background of the described technology, and therefore it may contain information that does not form the prior art that is already known in this country to a person of ordinary skill in the art.

### SUMMARY

The described technology has been made in an effort to provide a circuit board and a method of fabricating a circuit board having advantages of implementing a connection pad for mounting a wire bonding chip with a fine pitch.

However, the problems to be solved by the embodiments are not limited to the above-described problems and may variously extend within the scope of the technical idea included in the present disclosure.

An embodiment provides a circuit board including: a substrate having a first surface and a second surface opposing each other; a first connection pad protruding from the first surface in a first direction perpendicular to the first surface of the substrate and having an upper surface and a side surface intersecting each other; a first conductive layer disposed on the upper surface of the first connection pad; and a second conductive layer disposed in contact with an upper surface of the first conductive layer and the side surface of the first connection pad.

The first conductive layer may not be positioned on the side surface of the first connection pad.

The second conductive layer may be positioned to integrally surround the first connection pad and the first conductive layer.

In a second direction parallel to the first surface of the substrate, the first conductive layer may have the same width as the first connection pad.

The circuit board may further include: a circuit layer disposed on the first surface of the substrate; and a first solder resist layer covering the circuit layer on the first surface of the substrate. The first solder resist layer may have a first opening overlapping the first connection pad in the first direction.

The first opening may have a larger planar area than the first connection pad.

An inner peripheral surface of the first opening may be spaced apart from the second conductive layer disposed on the side surface of the first connection pad.

The first solder resist layer may have a larger thickness in the first direction than the first connection pad.

In the first direction, the first solder resist layer may have a thickness greater than a sum of a thickness of the first connection pad and a thickness of first conductive layer.

The first conductive layer may be further disposed on an upper surface of the circuit layer.

The first conductive layer may include a nickel (Ni) conductive layer, and the second conductive layer may include a gold (Au) conductive layer.

The circuit board may further include: a second connection pad positioned on the second surface of the substrate; and a second solder resist layer having a second opening overlapping the second connection pad in the first direction on the second surface of the substrate.

The second opening may have a smaller planar area than the second connection pad.

The substrate may include a plurality of insulating layers, and each of the plurality of insulating layers may include a circuit layer.

Another embodiment provides a method of fabricating a circuit board including: forming a first plating resist on a first surface of a substrate having a seed layer and forming openings in the first plating resist; forming a circuit layer and a first connection pad on the seed layer in the openings, respectively, by a plating process; forming a first conductive layer by performing a plating process on the circuit layer and the first connection pad; stripping the first plating resist from the substrate; removing a portion of the seed layer between the circuit layer and the first connection pad from the substrate; forming a solder resist layer having an opening overlapping the first connection pad on the first surface of the substrate; and forming a second conductive layer by performing a plating process on surfaces of the first conductive layer and the first connection pad.

The method may further include: applying a second plating resist covering the first connection pad while exposing the circuit layer; and etching and removing the first conductive layer disposed on the circuit layer.

The forming of the circuit layer and the first connection pad may include performing plating such that the first connection pad has a smaller thickness than the first plating resist.

The forming of the first conductive layer may include performing plating such that an upper surface of the first conductive layer is positioned lower than an upper surface of the first plating resist.

The forming of the solder resist layer may include forming a first solder resist layer such that an inner peripheral surface of the opening of the solder resist layer is spaced apart from the first connection pad.

The forming of the second conductive layer may include forming the second conductive layer to integrally surround the first connection pad and the first conductive layer.

In the circuit board and the method of fabricating the circuit board according to the embodiments, the connection pad for mounting a wire bonding chip can be implemented with a fine pitch.

### BRIEF DESCRIPTION OF THE DRAWINGS

FIG. 1 is a cross-sectional view illustrating a circuit board according to an embodiment.

FIGS. 2 to 8 are process cross-sectional views illustrating a method of fabricating the circuit board shown in FIG. 1.

FIG. 9 is a cross-sectional view illustrating a circuit board according to another embodiment.

### DETAILED DESCRIPTION

Hereinafter, embodiments will be described in detail with reference to the accompanying drawings so that they can be easily carried out by those of ordinary skill in the art to which the present disclosure pertains. In order to clearly describe the present disclosure, parts irrelevant to the description are omitted in the drawings, and the same or similar components will be denoted by the same reference signs throughout the specification. In the accompanying drawings, some components are exaggerated, omitted, or schematically illustrated, and a size of each component does not entirely reflect the actual size.

The accompanying drawings are provided only to help easily understand the embodiments disclosed in the present specification, and it should be understood that the technical spirit disclosed in the present specification is not limited by the accompanying drawings, and the present disclosure includes all modifications, equivalents, and substitutions falling within the spirit and the technical scope of the present disclosure.

Terms including ordinal numbers such as first and second may be used to describe various components, but these components are not limited by these terms. These terms are used only for the purpose of distinguishing one component from another component.

In addition, when a part such as a layer, a film, a region, or a plate is referred to as being “on” another part, it may be “directly on” the another part or there may be an intervening part therebetween. In contrast, when a part is referred to as being “directly on” another part, there is no intervening part therebetween. In addition, when a part is referred to as being “on” a reference part, it is positioned on or under the reference part, and does not necessarily mean that it is positioned “on” the reference part in the opposite direction of gravity.

It should be understood that terms “include”, “have”, and the like used throughout the specification specify the presence of features, numerals, steps, operations, components, parts mentioned in the specification, or a combination thereof, but do not preclude the presence or addition of one or more other features, numerals, steps, operations, components, parts, or a combination thereof. Therefore, when a certain part is referred to as “including” a certain component, this implies the presence of other components, not precluding the presence of other components, unless explicitly stated to the contrary.

In addition, throughout the specification, the phrase “in a plan view” means when a target part is viewed from above, and the phrase “in a cross-sectional view” means when a cross section of a target part as vertically cut is viewed laterally.

In addition, throughout the specification, the expression “connected” means that two or more components are connected to each other not only in a direct manner but also in an indirect manner through another component, means that two or more component are connected to each other not only physically but also electrically, or means that two or more components are integrally formed even though they are referred to by different terms based on their positions and functions.

Throughout the specification, a substrate is wide in a plane view and thin in a cross-sectional view. Also, unless otherwise defined, a “planar direction of the substrate” may refer to a direction parallel to a wide and flat surface of the substrate, and a “thickness direction of the substrate” may refer to a direction perpendicular to the wide and flat surface of the substrate.

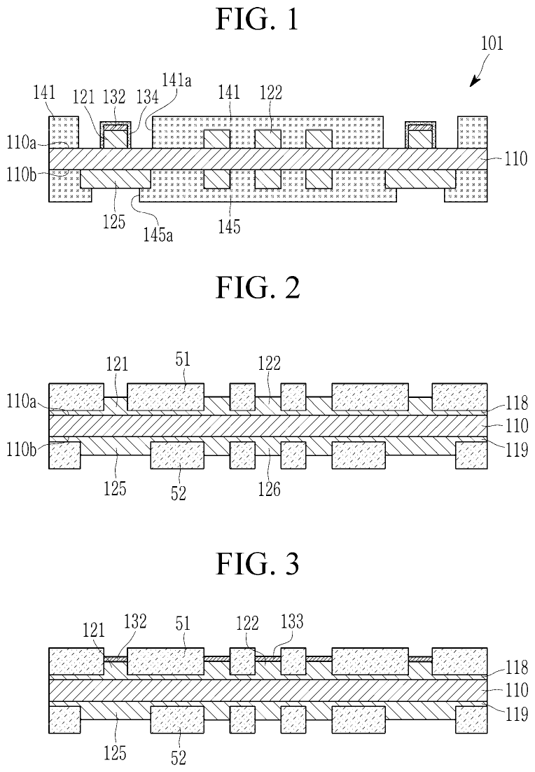

FIG. 1 is a cross-sectional view illustrating a circuit board according to an embodiment.

Referring to FIG. 1, a circuit board 101 according to the present embodiment includes a substrate 110 and a first connection pad 121 formed to protrude on the substrate 110. The circuit board 101 may be used for a semiconductor package and may be configured as a printed circuit board.

The substrate 110 may have a first surface 110a and a second surface 110b opposing each other. The first connection pad 121 may protrude in a thickness direction of the substrate 110, that is, in a first direction perpendicular to the surfaces of the substrate 110 from the first surface 110a of the substrate 110. Therefore, the first connection pad 121 may have an upper surface and a side surface intersecting each other. In this case, the upper surface of the first connection pad 121 may be formed parallel to the surfaces of the substrate 110 and toward the first direction, and the side surface of the first connection pad 121 may be formed perpendicular to the surfaces of the substrate 110 and toward a second direction perpendicular to the first direction. Here, the first connection pad 121 may include a copper (Cu) layer.

The substrate 110 may include a resin insulating layer. For the substrate 110, a thermosetting resin such as an epoxy resin, a thermoplastic resin such as polyimide, or a resin formed by impregnating a reinforcing material such as a glass fiber or an inorganic filler in the thermosetting resin or the thermoplastic resin, for example, prepreg, may be used. Alternatively, the substrate 110 may include a thermosetting resin and/or a photocurable resin, but is not limited thereto.

A first conductive layer 132 may be disposed on the upper surface of the first connection pad 121. The first conductive layer 132 may include a nickel (Ni) conductive layer. A second conductive layer 134 may be disposed in contact with an upper surface of the first conductive layer 132 and the side surface of the first connection pad 121. The second conductive layer 134 may include a gold (Au) conductive layer, and may be positioned to integrally surround the first connection pad 121 and the first conductive layer 132.

In the present embodiment, the first conductive layer 132 may be positioned in contact with the first connection pad 121, but is not positioned on the side surface of the first connection pad 121. Therefore, when measured in the second direction parallel to the surfaces of the substrate 110, the first conductive layer 132 may have the same width as the first connection pad 121.

In the present embodiment, the first conductive layer 132 and the second conductive layer 134 may be formed by electrolytic plating or electroless plating. That is, as a method for forming the nickel conductive layer and the gold conductive layer, nickel/gold metal films may be formed by applying a current to the first connection pad 121 containing copper, or nickel/gold metal films may be formed through a chemical reduction reaction without applying electric energy.

A circuit layer 122 may be disposed on the first surface 110a of the substrate 110, and a first solder resist layer 141 may be applied to cover the circuit layer 122. The first solder resist layer 141 may have a first opening 141a overlapping the first connection pad 121 in the first direction. The first opening 141a may have a larger planar area than the first connection pad 121, and in this case, an inner peripheral surface of the first opening 141a may be spaced apart from the second conductive layer 134 disposed on the side surface of the first connection pad 121.

In addition, the first solder resist layer 141 may have a larger thickness in the first direction than the first connection pad 121. That is, when measured from the first surface 110a of the substrate 110, the first connection pad 121 may have a lower height than the first solder resist layer 141. In this case, the first conductive layer 132 may form an interface with the first connection pad 121 at a position lower than an upper surface of the first solder resist layer 141, and a height of the first conductive layer 132 may be lower than a height of the upper surface of the first solder resist layer 141.

The substrate 110 may include a wire bonding pad having a bond finger region. In this case, the first connection pad 121 may constitute a bond finger for the wire bonding pad, and thus, a conductive wire may be bonded to the first connection pad 121 to wire-bond a semiconductor chip.

A second connection pad 125 may be further formed on the second surface 110b of the substrate 110. A second solder resist layer 145 having a second opening 145a overlapping the second connection pad 125 in the first direction may be formed on the second surface 110b of the substrate 110. The second opening 145a may have a smaller planar area than the second connection pad 125.

Although it is illustrated in FIG. 1 that the circuit board 101 has connection pads 121 and 125 on both surfaces of the substrate 110, respectively, the second connection pad 125 disposed on the second surface 110b of the substrate 110 may be omitted, which also falls within the scope of the present disclosure. Furthermore, the substrate 110 may include a plurality of insulating layers, and each of the plurality of insulating layers may include a circuit layer. Therefore, circuit layers may be formed on three or more insulating layers, respectively, and vias may extend in the thickness direction of the insulating layers to connect these circuit layers to each other.

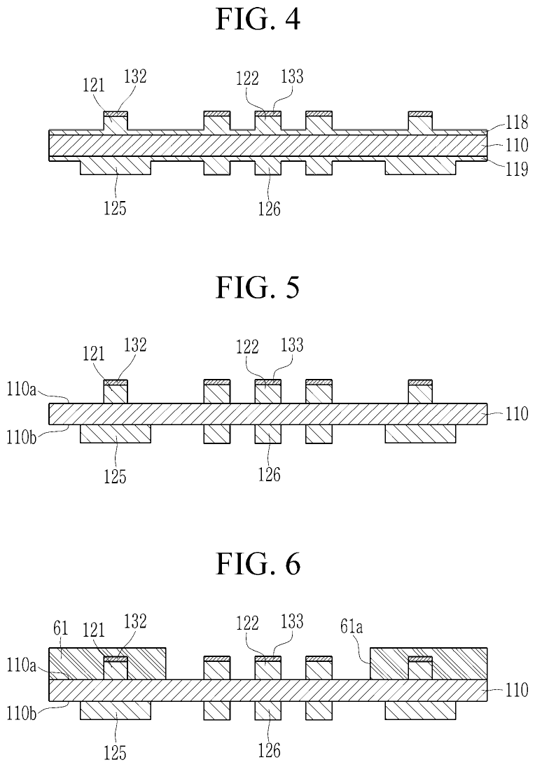

FIGS. 2 to 8 are process cross-sectional views illustrating a method of fabricating the circuit board shown in FIG. 1. A method of fabricating a circuit board according to an embodiment will be described with reference to FIGS. 2 to 8 together with FIG. 1.

As illustrated in FIG. 2, a first plating resist 51 is applied on a first surface 110a of a substrate 110 having a seed layer 118, the first plating resist 51 is patterned, and then a plating process is performed to form a circuit layer 122 and a first connection form pad 121. At this time, the plating may be performed such that the first connection pad 121 has a smaller thickness than the first plating resist 51. Similarly, a second plating resist 52 is applied on a second surface 110b of the substrate 110 having a seed layer 119, the second plating resist is patterned, and then a plating process is performed to form a circuit layer 126 and a second connection pad 125.

The substrate 110 may include a resin insulating layer. For the substrate 110, a thermosetting resin such as an epoxy resin, a thermoplastic resin such as polyimide, or a resin formed by impregnating a reinforcing material such as a glass fiber or an inorganic filler in the thermosetting resin or the thermoplastic resin, for example, prepreg, may be used. Alternatively, the substrate 110 may include a thermosetting resin and/or a photocurable resin, but is not limited thereto. In addition, the seed layers 118 and 119 may be applied without limitation as long as they are used as conductive metals for circuits in the circuit board field, and copper is generally used therefor.

According to the embodiment as illustrated, it is illustrated that two circuit layers 122 and 126 are included on both surfaces of the substrate 110, respectively, but the present disclosure is not limited thereto. A larger number of insulating layers and more circuit patterns may be included, which also falls within the scope of the present disclosure.

Referring to FIG. 3, a first conductive layer 132/133 is formed by performing a plating process on the circuit layer 122 and the first connection pad 121. At this time, the plating may be performed such that an upper surface of the first conductive layer 132/133 is positioned lower than an upper surface of the first plating resist 51. The first conductive layer 132/133 may include a nickel conductive layer. Accordingly, the nickel conductive layer may be formed to have a constant width on an upper surface of the first connection pad 121, and the nickel conductive layer is not formed on a side surface of the first connection pad 121.

Referring to FIGS. 4 and 5, the first plating resist 51 is stripped from the substrate 110, and the seed layers 118 and 119 are removed from the substrate 110 by quick etching. As a result, the circuit layer 122 and the first connection pad 121 are formed on the first surface 110a of the substrate 110, and the first conductive layer 132/133 is formed on each of the upper surfaces of the circuit layer 122 and the first connection pad 121. Also, the circuit layer 126 and the second connection pad 125 may be formed on the second surface 110b of the substrate 110.

Referring to FIG. 6, a third plating resist 61 is applied to cover the first connection pad 121 while exposing the circuit layer 122. That is, the third plating resist 61 may be patterned and applied to have an opening 61a overlapping the circuit layer 122.

Referring to FIG. 7, the first conductive layer 133 disposed on the circuit layer 122 is removed by etching. Then, the third plating resist 61 is stripped.

Referring to FIG. 8, a first solder resist layer 141 having a first opening 141a overlapping the first connection pad 121 is formed on the first surface 110a of the substrate 110. The first solder resist layer 141 may be formed such that an inner peripheral surface of the first opening 141a is spaced apart from the first connection pad 121.

Similarly, a second solder resist layer 145 having a second opening 145a overlapping the second connection pad 125 may be formed on the second surface 110b of the substrate 110.

The solder resist layers 141 and 145 function as protective layers to protect outermost circuits, and are formed for electrical insulation. The solder resist layers 141 and 145 may be formed of, for example, a solder resist ink, a solder resist film, an encapsulant, or the like as known in the art, but are not particularly limited thereto.

Then, as illustrated in FIG. 1, a second conductive layer 134 is formed by performing a plating process on the surfaces of the first conductive layer 132 and the first connection pad 121. The second conductive layer 134 may be formed to integrally surround the first connection pad 121 and the first conductive layer 132. The second conductive layer 134 may include a gold (Au) conductive layer.

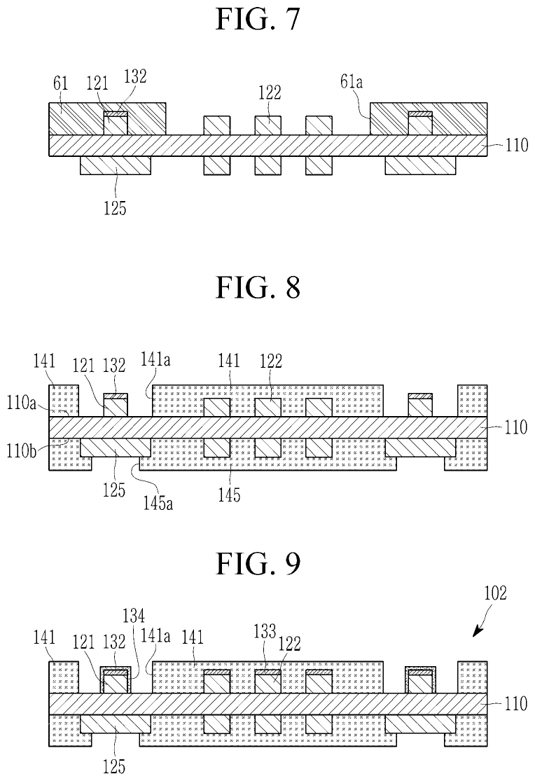

FIG. 9 is a cross-sectional view illustrating a circuit board 102 according to another embodiment.

In the fabricating method described with reference to FIGS. 2 to 8, the processes shown in FIGS. 6 and 7 may be selectively omitted. That is, the process shown in FIG. 8 may be performed directly without removing the first conductive layer 133 formed on the upper surface of the circuit layer 122 disposed on the first surface 110a of the substrate 110. At this time, as illustrated in FIG. 9, the circuit layer 122 may be covered with the first solder resist layer 141 in a state where the first conductive layer 133 positioned on the upper surface of the circuit layer 122 is maintained. The other configurations are the same as those in the embodiment shown in FIG. 1, and thus, redundant descriptions are omitted.

Although the preferred embodiments have been described above, the present disclosure is not limited thereto, and various modifications may be made within the scope of the claims, the specification, and the accompanying drawings, which also fall within the scope of the present disclosure.

What is claimed is:

1. A circuit board comprising:
a substrate having a first surface and a second surface opposing each other;
a first connection pad protruding from the first surface in a first direction perpendicular to the first surface of the substrate and having an upper surface and a side surface intersecting each other;
a first conductive layer disposed on the upper surface of the first connection pad; and
a second conductive layer disposed in contact with an upper surface of the first conductive layer and the side surface of the first connection pad.

2. The circuit board of claim 1, wherein
the first conductive layer is not positioned on the side surface of the first connection pad.

3. The circuit board of claim 1, wherein
the second conductive layer is positioned to integrally surround the first connection pad and the first conductive layer.

4. The circuit board of claim 1, wherein
in a second direction parallel to the first surface of the substrate, the first conductive layer has the same width as the first connection pad.

5. The circuit board of claim 1, further comprising:
a circuit layer disposed on the first surface of the substrate; and
a first solder resist layer covering the circuit layer on the first surface of the substrate,
wherein the first solder resist layer has a first opening overlapping the first connection pad in the first direction.

6. The circuit board of claim 5, wherein
the first opening has a larger planar area than the first connection pad.

7. The circuit board of claim 5, wherein
an inner peripheral surface of the first opening is spaced apart from the second conductive layer disposed on the side surface of the first connection pad.

8. The circuit board of claim 5, wherein
the first solder resist layer has a larger thickness in the first direction than the first connection pad.

9. The circuit board of claim 5, wherein
in the first direction, the first solder resist layer has a thickness greater than a sum of a thickness of the first connection pad and a thickness of first conductive layer.

10. The circuit board of claim 5, wherein
the first conductive layer is further disposed on an upper surface of the circuit layer.

11. The circuit board of claim 1, wherein
the first conductive layer includes a nickel (Ni) conductive layer, and
the second conductive layer includes a gold (Au) conductive layer.

12. The circuit board of claim 1, further comprising:
a second connection pad positioned on the second surface of the substrate; and
a second solder resist layer having a second opening overlapping the second connection pad in the first direction on the second surface of the substrate.

13. The circuit board of claim 12, wherein
the second opening has a smaller planar area than the second connection pad.

14. The circuit board of claim 1, wherein
the substrate includes a plurality of insulating layers, and
each of the plurality of insulating layers includes a circuit layer.

15. A method of fabricating a circuit board, the method comprising:
forming a first plating resist on a first surface of a substrate having a seed layer and forming openings in the first plating resist;
forming a circuit layer and a first connection pad on the seed layer in the openings, respectively, by a plating process;
forming a first conductive layer by performing a plating process on the circuit layer and the first connection pad;
stripping the first plating resist from the substrate;
removing a portion of the seed layer between the circuit layer and the first connection pad from the substrate;
forming a solder resist layer having an opening overlapping the first connection pad on the first surface of the substrate; and
forming a second conductive layer by performing a plating process on surfaces of the first conductive layer and the first connection pad.

16. The method of claim 15, further comprising:
applying a second plating resist covering the first connection pad while exposing the circuit layer; and
etching and removing the first conductive layer disposed on the circuit layer.

17. The method of claim 15, wherein
the forming of the circuit layer and the first connection pad includes performing plating such that the first connection pad has a smaller thickness than the first plating resist.

18. The method of claim 17, wherein
the forming of the first conductive layer includes performing plating such that an upper surface of the first conductive layer is positioned lower than an upper surface of the first plating resist.

19. The method of claim 15, wherein
the forming of the solder resist layer includes forming a first solder resist layer such that an inner peripheral surface of the opening of the solder resist layer is spaced apart from the first connection pad.

20. The method of claim 15, wherein
the forming of the second conductive layer includes forming the second conductive layer to integrally surround the first connection pad and the first conductive layer.
